(19) United States
(12) Patent Application Publication
(10) Pub. No.: US 2013/0256510 A1
(43) Pub. Date: Oct. 3, 2013

(54) IMAGING DEVICE WITH FLOATING DIFFUSION SWITCH

(71) Applicant: Jeong-Ho Lyu, San Jose, CA (US)

(72) Inventor: Jeong-Ho Lyu, San Jose, CA (US)

(73) Assignee: OMNIVISION TECHNOLOGIES, INC., Santa Clara, CA (US)

(21) Appl. No.: 13/434,124

(22) Filed: Mar. 29, 2012

(51) Int. Cl. H01L 27/148; H01L 27/144

(52) U.S. Cl. 250/208.1; 250/206

(57) ABSTRACT

Embodiments of the invention describe utilizing dual floating diffusion switches to enhance the dynamic range of pixels having multiple photosensitive elements. The insertion of dual floating diffusion switches between floating diffusion nodes of said photosensitive elements allows the conversion gain to be controlled and selected for each photosensitive element of a pixel. Furthermore, in embodiments utilizing a photosensitive element for high conversion gains, the value of high conversion gain for the respective photosensitive element maybe increased due to the separation between floating diffusion nodes, enabling high sensitivity for low-light conditions.

### TECHNICAL FIELD

This disclosure relates generally to image capture devices, and in particular but not exclusively, relates to enhancing the dynamic range of image capture devices.

### BACKGROUND INFORMATION

Image sensors have become ubiquitous. They are widely used in digital still cameras, cellular phones, security cameras, as well as, medical, automobile, and other applications. The technology used to manufacture image sensors, and in particular, complementary metal-oxide-semiconductor (“CMOS”) image sensors (“CIS”), has continued to advance at great pace. For example, the demands of higher resolution and lower power consumption have encouraged the further miniaturization and integration of these image sensors.

FIG. 1 is a circuit diagram illustrating pixel circuitry of two four-transistor (“4T”) pixel cells Pa and Pb (shown as pixel cells 100 and 150, respectively) within an image sensor array. Pixel cells Pa and Pb are arranged in two rows and one column and time share a single readout column line or bit line. Pixel cell 100 includes photodiode 110, transfer transistor 101, reset transistor 102, source-follower (“SF”) or amplifier (“AMP”) transistor 103, and row select (“RS”) transistor 104. Pixel cell 150 similarly includes photodiode 160, transfer transistor 151, reset transistor 152, SF transistor 153, and RS transistor 154.

During operation of pixel cell 100, said transfer transistor receives transfer signal TX, which transfers the charge accumulated in photodiode 110 to floating diffusion (FD) node 105. Reset transistor 102 is coupled between a power rail VDD and FD node 105 to reset the pixel (e.g., discharge or charge the FD and the PD to a preset voltage) under control of a reset signal RST. FD node 105 is coupled to control the gate of AMP transistor 103. AMP transistor 103 is coupled between the power rail VDD and RS transistor 104. AMP transistor 103 operates as a source-follower providing a high impedance connection to FD node 105. Finally, RS transistor 104 selectively couples the output of the pixel circuitry to readout the image data in the pixel to the bit line under control of a signal RS. Pixel cell 150 also includes an FD node (shown as node 155) and is configured in a similar manner as pixel cell 100.

The conversion gain of pixel cells 100 and 150 is inversely proportional to the capacitance of their respective FD nodes. A high conversion gain can be beneficial to improve low-light sensitivity. For traditional image sensors, conversion gain can be increased by reducing the capacitance of an FD node; however, as pixel cell sizes shrink, and the capacitance of FD nodes decrease, and thus pixel saturation or overexposure in bright environments becomes more acute. What is needed is a solution for multi-photodiode pixels to achieve a high dynamic range and a large conversion gain range.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. The drawings are not necessarily to scale, emphasis instead being placed upon illustrating the principles being described.

FIG. 1 is a diagram illustrating prior art pixel circuitry of two four-transistor pixel cells.

FIG. 2 is a functional block diagram illustrating an imaging system in accordance with an embodiment of the disclosure.

FIG. 3 is a diagram illustrating a two-shared pixel cell with a dual floating-diffusion switch in accordance with an embodiment of the disclosure.

FIG. 4 is a diagram illustrating a two-shared pixel cell with a dual floating-diffusion switch in accordance with an embodiment of the disclosure.

FIG. 5 is a timing diagram showing the method of reading out a two-shared pixel cell with a dual floating-diffusion switch in accordance with an embodiment of the disclosure.

FIG. 6 is a circuit diagram illustrating a four-shared pixel cell with two dual floating-diffusion switches in accordance with an embodiment of the disclosure.

FIG. 7 is a timing diagram showing the method of reading out a four-shared pixel cell in accordance with an embodiment of the disclosure.

Descriptions of certain details and implementations follow, including a description of the figures, which may depict some or all of the embodiments described below, as well as discussing other potential embodiments or implementations of the inventive concepts presented herein. An overview of embodiments of the invention is provided below, followed by a more detailed description with reference to the drawings.

### DETAILED DESCRIPTION

Embodiments of an image sensor comprising pixel cells with floating diffusion switches to enhance the dynamic range of the image capture device and methods of operation are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

References throughout this specification to “one embodiment” or “an embodiment” means that a particular feature, structure, process, block or characteristic described in connection with an embodiment included in at least one embodiment of the present invention. Thus, the appearance of the phrases “in one embodiment” or “in an embodiment” in various places throughout this specification does not necessarily mean that the phrases all refer to the same embodiment. The particular features, structures or characteristics may be combined with any suitable manner in one or more embodiments.

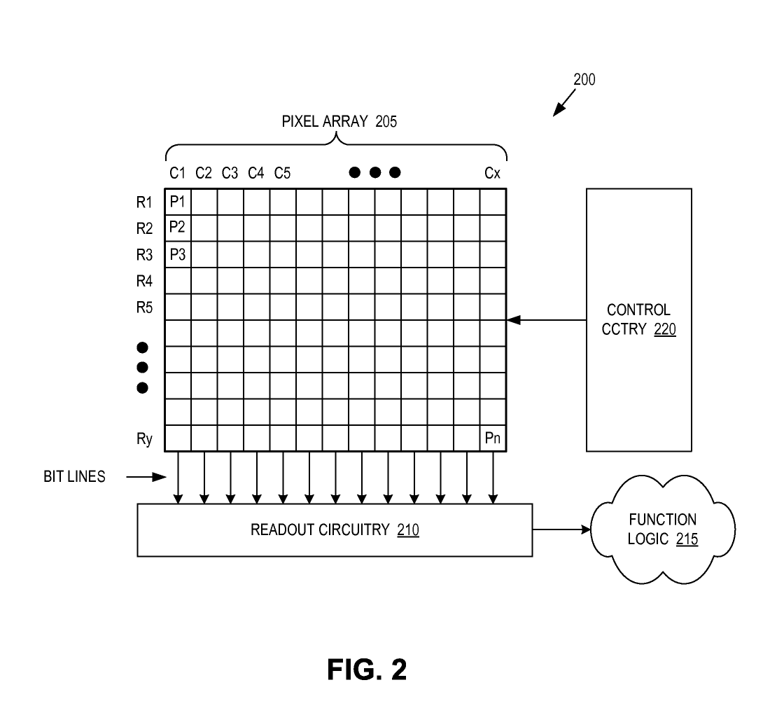

FIG. 2 is a functional block diagram illustrating an imaging system in accordance with an embodiment of the disclosure. The illustrated embodiment imaging system 200 includes pixel array 205, readout circuitry 210, function logic 215 and control circuitry 220.

Pixel array 205 is a two-dimensional (2D) array of imaging sensor cells or pixel cells (e.g., pixels P1, P2, . . . , Pn). In one embodiment, each pixel cell is a complementary metal-oxide-semiconductor (CMOS) imaging pixel. Pixel array 205 may be implemented as a front-side illuminated image sensor or a backside illuminated image sensor. As illustrated, each pixel cell is arranged into a row (e.g., rows R1 to Ry) and a column (e.g., column C1 to Cx) to acquire image data of a person, place or object, which can then be used to render an image of the person, place or object.

After each pixel has acquired its image data or image charge, the image data is readout by readout circuitry 210 and transferred to function logic 215. Readout circuitry 210 may include column amplification circuitry, analog-to-digital (ADC) conversion circuitry, or otherwise. Function logic 215 may simply store the image data or even manipulate the image data by applying post image effects (e.g., crop, rotate, remove red eye, adjust brightness, adjust contrast or otherwise). In one embodiment, readout circuitry 210 may readout a row of image data at a time along readout column lines or may readout the image data using a variety of other techniques (not illustrated), such as serial readout, column readout along readout row lines, or a full parallel readout of all pixels simultaneously. It should be appreciated that the designation of a line of pixel cells within pixel array 205 as either a row or a column is arbitrary and one of rotational perspective. As such, the use of the terms “row” and “column” are intended merely to differentiate the two axes relative to each other.

Control circuitry 220 is coupled to pixel array 205 and includes logic and driver circuitry for controlling operational characteristics of pixel array 205. For example, reset, row select, and transfer signals may be generated by control circuitry 220. Control circuitry 220 may include a row driver, as well as other control logic.

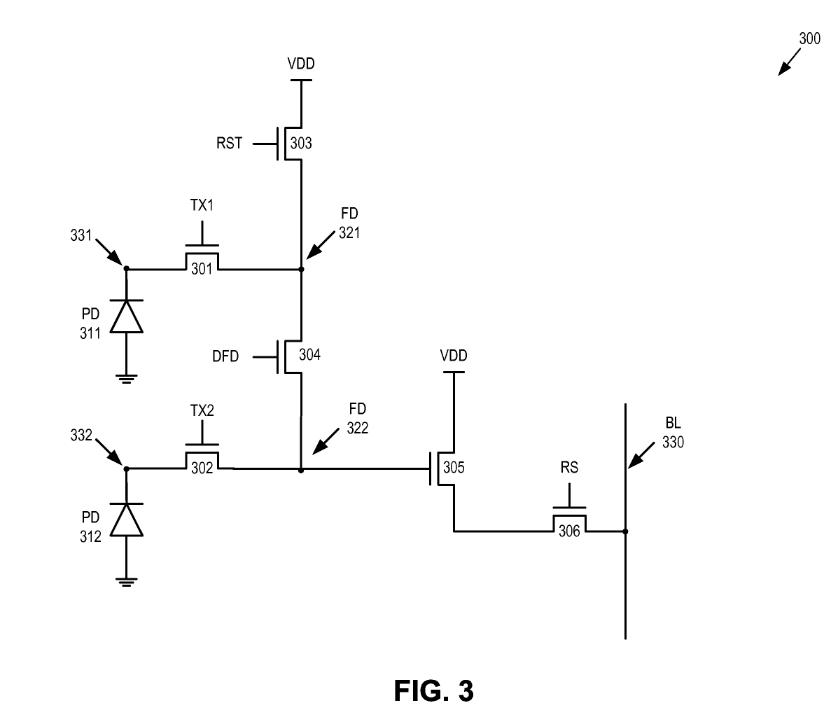

FIG. 3 is a diagram illustrating a two-shared pixel cell with a dual floating-diffusion switch in accordance with an embodiment of the disclosure. Pixel circuitry 300 is one possible pixel circuitry architecture for implementing each pixel cell within pixel array 205 of FIG. 2. However, it should be appreciated that the teachings disclosed herein are not limited to the illustrated pixel architecture; rather, one of ordinary skill in the art having the benefit of the instant disclosure will understand that the present teachings are also applicable to various other pixel architectures.

Two-shared pixel cell 300 comprises a plurality of photosensitive regions, including photodiodes 311 and 312, transfer transistors 301 and 302, reset transistor 303, dual floating-diffusion switch 304, source-follower (“SF”) or amplifier (“AMP”) transistor 305 and row select transistor 306.

Transfer transistors 301 and 302 of two-shared pixel cell 300 are each coupled to a pair of nodes—transistor 301 is shown to be coupled to node 331 and floating diffusion node 321, while transistor 302 is shown to be coupled to node 332 and floating diffusion node 322. Nodes 331 and 332 are respectively coupled to photodiodes 311 and 312. During operation, transfer transistor 301 receives transfer signal TX1, which transfers the charge accumulated in photodiode 311 to floating diffusion node 321. Transfer transistor 302 receives transfer signal TX2, which transfers the charge accumulated in photodiode 312 to floating diffusion node 322.

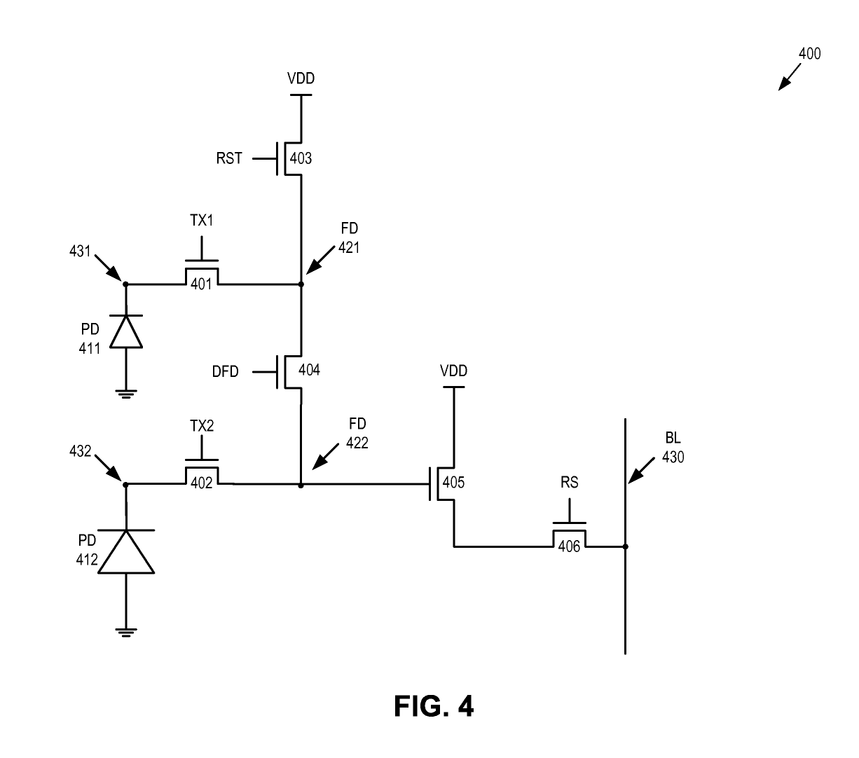

In this embodiment, photodiodes 311 and 312 are illustrated to have relatively the same photosensitivity. In other embodiments (such as pixel 400 of FIG. 4 described below), photodiodes 311 and 312 may have different photosensitivities.

In this embodiment, pixel 300 includes dual floating-diffusion switch 304 coupled between floating diffusion nodes 321 and 322 for selectively coupling floating diffusion nodes 321 and 322 under the control of dual floating-diffusion node signal DFD. By switching dual floating-diffusion switch 304 on and off under the control of dual floating diffusion node signal DFD, the capacitance of floating diffusion node 321 can be selectively supplemented (e.g., increased over the inherent capacitance of floating diffusion node 322), thereby changing the conversion gain of two-shared pixel cell 300. In this embodiment, when dual floating-diffusion node signal DFD is de-asserted, the inherent capacitance of floating diffusion node 322 is available for the readout of photodiode 312. When dual floating-diffusion node signal DFD is asserted, the inherent capacitances of floating diffusion nodes 321 and 322 are available for the readout of either photodiode 311 or 312. By changing the capacitance available for the readout of a photodiode, the conversion gain maybe adjusted.

In this embodiment, reset transistor 303 is coupled between power rail VDD and floating diffusion node 321 to reset two-shared pixel cell 300 under control of reset signal RST. Reset transistor 303 may further be coupled to floating diffusion node 322 to reset two-shared pixel cell 300. The gate terminal of SF transistor 305 is coupled to floating diffusion node 322. SF transistor 305 is coupled between power rail VDD and bit line 330 and operates as a source-follower providing a high impedance connection to floating diffusion node 322. Row select transistor 306 selectively couples bit line 330 to SF transistor 305 under control of a row select signal RS. In one embodiment, said row select transistor may be omitted and SF transistor 305 may be connected to bit line 330. In this embodiment, SF transistor 305 is coupled between a row select power rail RSVDD and bit line 330.

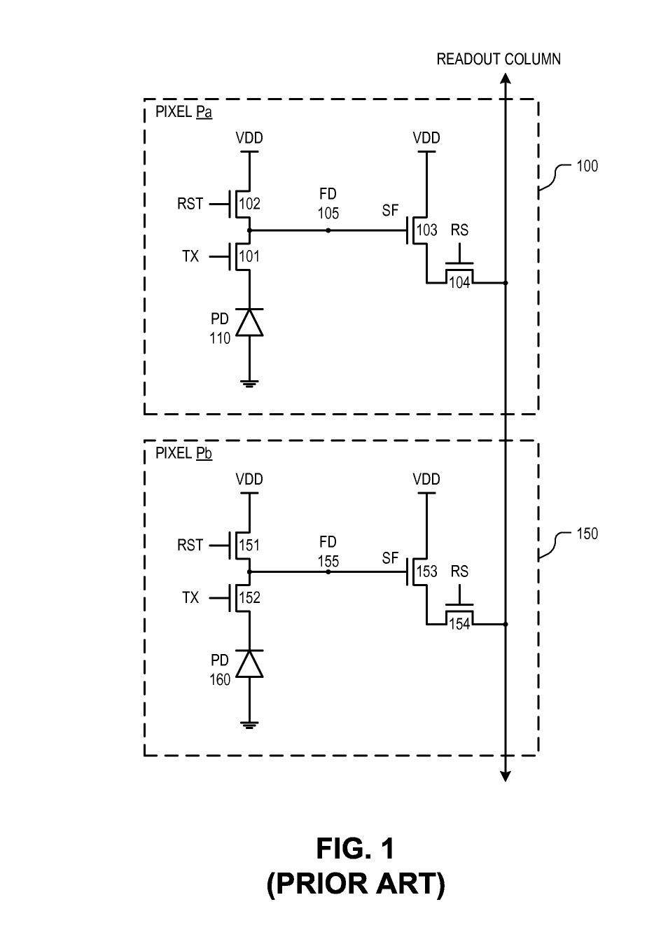

In this embodiment, the presence of dual floating-diffusion switch 304 separates floating diffusion nodes 321 and 322 and reduces the amount of metal interconnect directly above floating diffusion nodes 321 and 322, thereby reducing the capacitance caused by metal interconnects used in prior art solutions (e.g., connection 110 of FIG. 1).

FIG. 4 is a diagram illustrating a two-shared pixel cell with a dual floating-diffusion switch in accordance with an embodiment of the disclosure. Similar to the embodiment illustrated in FIG. 3, two-shared pixel cell 400 comprises a plurality of photosensitive regions, including photodiodes 411 and 412, transfer transistors 401 and 402, reset transistor 403, dual floating-diffusion switch 404, source-follower (“SF”) or amplifier (“AMP”) transistor 405 and row select transistor 406.

Transfer transistors 401 and 402 of two-shared pixel cell 400 are each coupled to a pair of nodes—transistor 401 is shown to be coupled to node 431 and floating diffusion node 421, while transistor 402 is shown to be coupled to node 432 and floating diffusion node 422. Nodes 431 and 432 are respectively coupled to photodiodes 411 and 412. Similar to the embodiment illustrated in FIG. 3, during operation transfer transistor 401 receives transfer signal TX1, which transfers the charge accumulated in photodiode 411 to floating diffusion node 421. Transfer transistor 402 receives transfer signal TX2, which transfers the charge accumulated in photodiode 412 to floating diffusion node 422.

In this embodiment of the invention, 411 and 412 have different photosensitivities, with photodiode 411 having a lower photosensitivity than photodiode 412. Factors which affect photosensitivity include the physical size of the photodiode and the concentration of dopant in the photodiode—in the illustrated embodiment, photodiode 412 is shown to be larger than photodiode 411. In other embodiments, said photodiodes may have varying photosensitivities due to factors other than size.

A photodiode with low photosensitivity may be beneficial to improve high-light image quality. Such a photodiode would require a low conversion gain and a greater floating diffusion capacitance. In this embodiment, the greater floating diffusion capacitance would be gained by coupling floating diffusion nodes 421 and 422 together.

A photodiode with high photosensitivity may be beneficial to improve low-light image quality. Such a photodiode would require a high conversion gain and a lower floating diffusion capacitance. In this embodiment, the lower floating diffusion capacitance would be achieved by isolating floating diffusion node 421 from 422.

Similar to the embodiment illustrated in FIG. 3, pixel 400 includes dual floating-diffusion switch 404 coupled between floating diffusion nodes 421 and 422 for selectively coupling floating diffusion nodes 421 and 422 under the control of dual floating-diffusion node signal DFD. By switching dual floating-diffusion switch 404 on and off under the control of dual floating diffusion node signal DFD, the capacitance of floating diffusion node 421 can be selectively supplemented (e.g., increased over the inherent capacitance of floating diffusion node 422), thereby changing the conversion gain of two-shared pixel cell 400. In this embodiment, when dual floating-diffusion node signal DFD is de-asserted, the inherent capacitance of floating diffusion node 422 is available for the readout of photodiode 412. When dual floating-diffusion node signal DFD is asserted, the inherent capacitances of floating diffusion nodes 421 and 422 are available for the readout of either photodiode 411 or 412. By changing the capacitance available for the readout of a photodiode, the conversion gain adjusted.

In this embodiment, reset transistor is coupled between power rail VDD and floating diffusion node 421 to reset two-shared pixel cell 400 under control of reset signal RST. Reset transistor may further be coupled to floating diffusion node 422 to reset two-shared pixel cell 400. The gate terminal of SF transistor 405 is coupled to floating diffusion node 422. SF transistor 405 is coupled between power rail VDD and bit line 430 and operates as a source-follower providing a high impedance connection to floating diffusion node 422. In other embodiments, a row select transistor may be included in two-shared pixel cell 400. Row select transistor 406 selectively couples the bit line 430 to SF transistor 405 under control of a row select signal RS. In one embodiment, the row select transistor may be omitted and SF transistor 405 is connected to bit line 430. In this embodiment, SF transistor 405 is coupled between a row select power rail RSVDD and bit line 430.

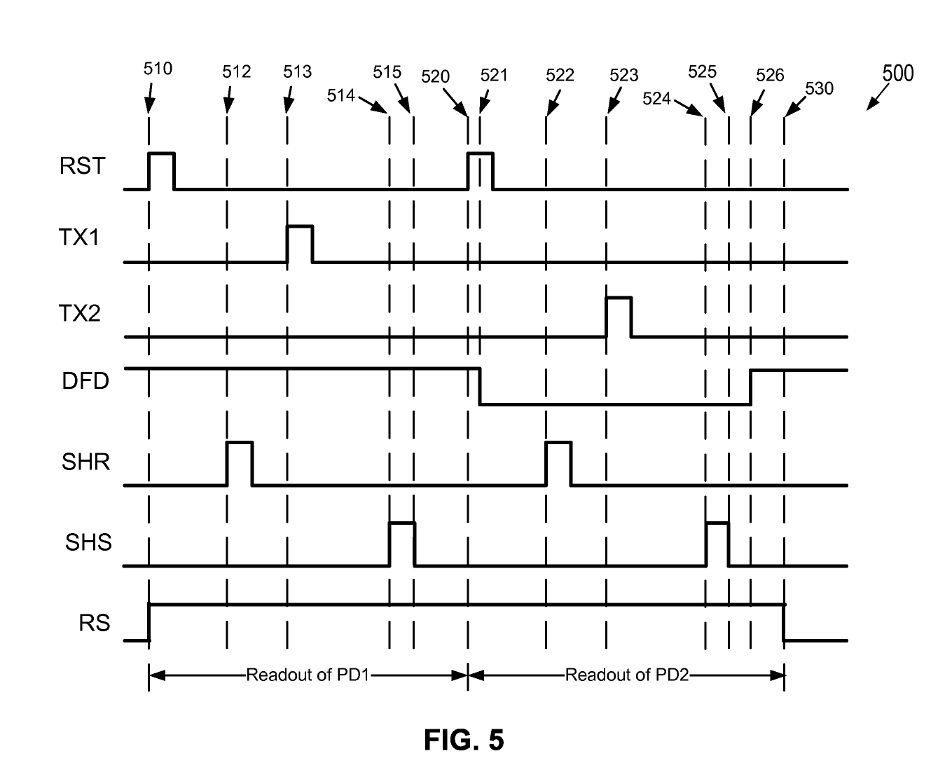

FIG. 5 is a timing diagram showing the method of reading out a two-shared pixel cell with a dual floating-diffusion switch in accordance with an embodiment of the disclosure. The description below for timing diagram 500 makes reference to the elements of pixel 400 of FIG. 4 for exemplary purposes only. At the end of an integration period (not shown in FIG. 5), the readout operation begins at time 510 with the reset of floating diffusions 421 and 422, which is done by asserting dual floating-diffusion node signal DFD and temporarily asserting reset signal RST. At time 510, row select signal RS is asserted. Then at time 512 sample reset signal SHR is temporarily asserted, which allows a sample and hold (“S&H”) circuit to sample the reset voltage. At time 513, with dual floating-diffusion node signal DFD, transfer signal TX1 is temporarily asserted, and charge accumulated in photodiode 411 is transferred to floating diffusion nodes 421 and 422. Then, at time 514, sample signal SHS is temporarily asserted, which allows the S&H circuit to sample the image voltage from floating diffusion nodes 421 and 422.

At time 520, the readout of photodiode 412 begins with the reset of floating diffusion 422, which is done by temporarily asserting reset signal RST. Dual floating-diffusion node signal DFD is not de-asserted until time 521, which occurs after time 520, but before reset signal RST is de-asserted. At time 522, sample reset signal SHR is temporarily asserted, which allows the S&H circuit to sample the reset voltage. At time 523, transfer signal TX2 is temporarily asserted, and charge accumulated in photodiode 412 is transferred to floating diffusion node 422. Then, at time 524, sample signal SHS is temporarily asserted, which allows the S&H circuit to sample the image voltage. At time 525, sample signal SHS is de-asserted. At some time 526, before the start of the readout of the next pixel cell, at time 530, dual floating-diffusion node signal DFD is asserted to couple floating diffusion nodes 421 and 422 to prepare them for reset or to reset photodiodes 411 and 412 before the next integration period, and row select signal RS is de-asserted.

In this embodiment, dual floating-diffusion node signal DFD does not need to be asserted to reset floating diffusion node 422. In other embodiments, said reset transistor may be coupled to floating diffusion node 422 such that dual floating-diffusion node signal DFD may be de-asserted at some time after time 515, and before time 520.

In another embodiment, row select transistor may be omitted, and SF transistor T5 is connected to bit line BL. In this embodiment, from time 510 to 530, during the readout of photodiodes 411 and 422, row select power rail RSVDD is asserted, during the integration of photodiodes 411 and 412, row select power rail RSVDD is de-asserted.

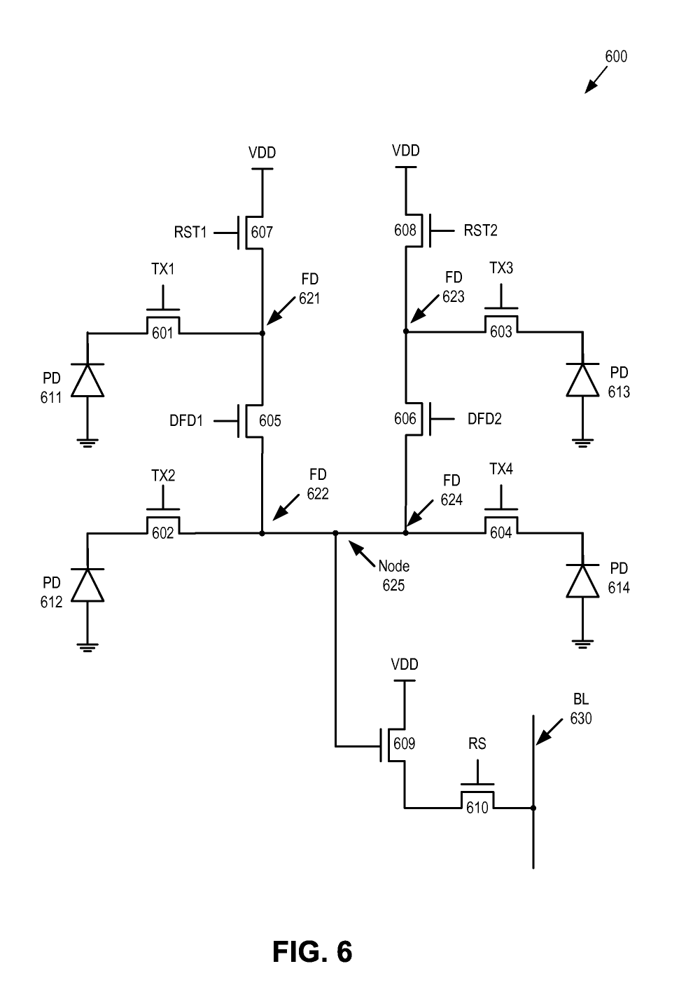

FIG. 6 is a circuit diagram illustrating a four-shared pixel cell with two dual floating-diffusion switches in accordance with an embodiment of the disclosure. Pixel circuitry 600 is one possible pixel circuitry architecture for implementing each pixel cell within pixel array 205 of FIG. 2. Four-shared pixel cell 600 is similar to the two-shared pixel cells FIG. 3 and FIG. 4. Four-shared pixel cell 600 comprises transfer transistors 601, 602, 603 and 604, photodiodes 611, 612, 613 and 614, dual floating-diffusion switches 605 and 606, reset transistors 607 and 608, SF or AMP transistor 609 and row select transistor 610.

Each transfer transistor of four-shared pixel cell 600 comprises a first and a second node. The first node of transfer transistors 601, 602, 603 and 604 are respectively coupled to photodiodes 611, 612, 613 and 614. During operation, transfer transistor 601 receives transfer signal TX1, which transfers the charge accumulated in photodiode 611 to the second node of transfer transistor 601, or floating diffusion node 621. Transfer transistors 602, 603 and 604, with their respective transfer signals, photodiodes and floating diffusion nodes, operate in a similar manner. Each transfer transistor is coupled between their respective photodiode and floating diffusion node, however, transfer transistors 602 and 604 are further coupled to the node 625. Photodiodes 611, 612, 613 and 614 may have the same photosensitivity, or may differ in any combination.

Dual floating-diffusion switches 605 and 606 are respectively coupled between floating diffusion nodes 621 and 622 and 623 and 624 under the control of dual floating-diffusion node signal DFD1 and DFD2 respectively. By switching dual floating-diffusion switch 605 (or 606) on and off under the control of dual floating diffusion node signal DFD1 (or DFD2), the capacitance of floating diffusion node 621 (or 623) can be selectively supplemented (e.g., increased over the inherent capacitance of floating diffusion node 622), thereby changing the conversion gain of four-shared pixel cell 600. When dual floating-diffusion node signal DFD1 (or DFD2) is de-asserted, the inherent capacitance of floating diffusion node 622 is available for the readout of photodiode 612 (or 614). When dual floating-diffusion node signal DFD is asserted, the inherent capacitances of floating diffusion nodes 621 and 622 (or 623 and 624) are available for the readout of either photodiode 611 or 612 (or 613 or 614). In four-shared pixel cell 600, the capacitance of floating diffusion nodes 621 and 623 can be supplemented to further adjust the conversion gain of the pixel cell by asserting dual floating-diffusion node signals DFD1 and DFD2 at the same time during the readout of any one of the four photodiodes in four-shared pixel cell 600. By changing the capacitance available for the readout of a photodiode, the conversion gain of pixel 600 may be adjusted.

Reset transistor 607 is coupled between power rail VDD and floating diffusion node 621, while reset transistor 608 is coupled between power rail VDD and floating diffusion node 623, to reset four-shared pixel cell 600 under control of reset signals RST1 and RST2. In one embodiment of the invention, reset transistor 607 or 608 may omitted so that only 1 reset transistor in each four-shared pixel cell 600 is used to reset the floating diffusion nodes of the pixel cell. In another embodiment of the invention, a single reset transistor is coupled to node 625 to reset the floating diffusion nodes of the pixel cell. The gate terminal of SF transistor 609 is coupled to floating diffusion node 622. SF transistor 609 is coupled between power rail VDD and bit line 630 and operates as a source-follower providing a high impedance connection to node 625. A row select transistor may selectively coupled the bit line 630 to SF transistor 609 under control of a row select signal RS. In one embodiment, the row select transistor may be omitted and SF transistor 609 is connected to bit line 630. In this embodiment, SF transistor 609 is coupled between a row select power rail RSVDD and bit line 630.

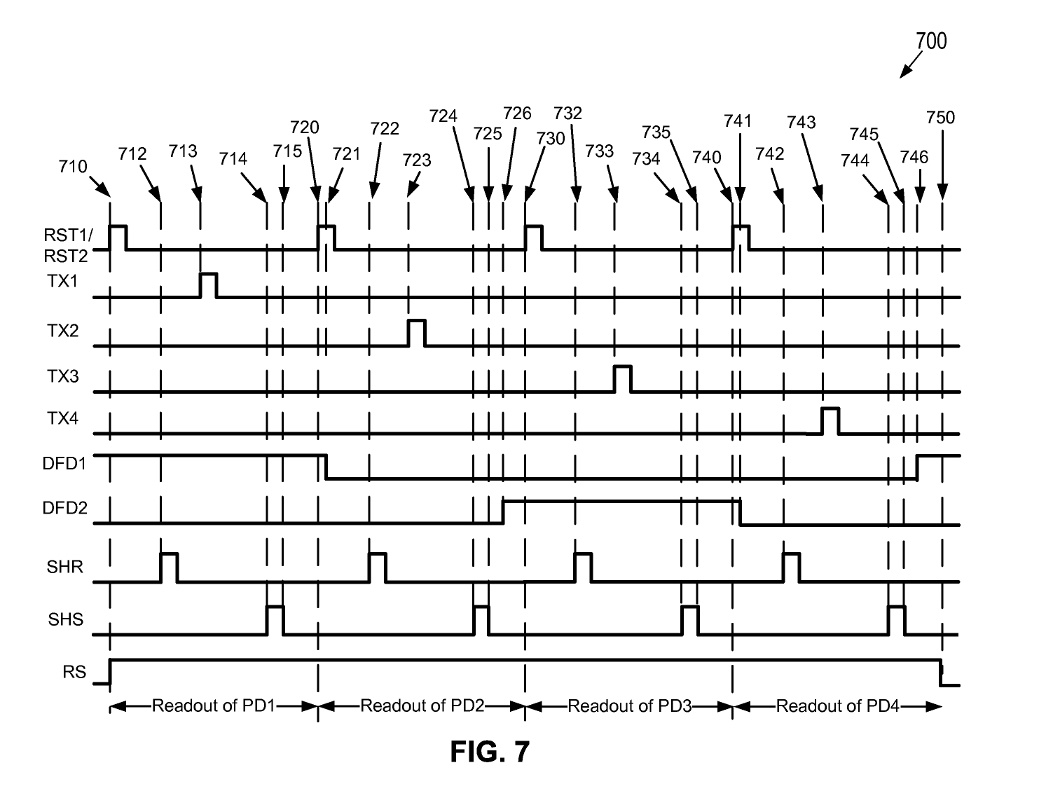

FIG. 7 is a timing diagram showing the method of reading out a four-shared pixel cell in accordance with an embodiment of the disclosure. The description below for timing diagram 700 makes reference to the elements of pixel 600 of FIG. 6 for exemplary purposes only. At the end of an integration period (not shown in FIG. 7), the readout operation begins at time 710 with the reset of floating diffusions 621 and 622, which is done by asserting dual floating-diffusion node signal DFD1 and temporarily asserting reset signal RST1 and RST2. At time 710, row select signal RS is asserted. Then at time 712, sample reset signal SHR is temporarily asserted, which allows a sample and hold (“S&H”) circuit to sample the reset voltage. At time 713, with dual floating-diffusion node signal, transfer signal TX1 is temporarily asserted, and charge accumulated in photodiode PD1 is transferred to floating diffusion nodes 621 and 622. Then, at time 714, sample signal SHS is temporarily asserted, which allows the S&H circuit to sample the image voltage from floating diffusion nodes 621 and 622. At time 715, sample signal SHS is de-asserted.

At time 720, the readout of photodiode PD2 begins with the reset of floating diffusion node 622, which is done by temporarily asserting reset signal RST1. Dual floating-diffusion node signal DFD1 is not de-asserted until time 721, which occurs after time 720, but before reset signal RST1 is de-asserted. At time 722, sample reset signal SHR is temporarily asserted, which allows the S&H circuit to sample the reset voltage. At time 723, transfer signal TX2 is temporarily asserted, and charge accumulated in photodiode 612 is transferred to floating diffusion node 622. Then, at time 724, sample signal SHS is temporarily asserted, which allows the S&H circuit to sample the image voltage. At time 725, sample signal SHS is de-asserted, row select signal RS is de-asserted. At some time 726, before the start of the readout of the next pixel cell, at time 730, dual floating-diffusion node signal DFD is asserted. Using the same methodology, photodiodes 613 and 614 are read out from time 730 to the end of the readout period, at time 750, at which time row select signal RS is de-asserted, as seen in FIG. 7.

In one embodiment, reset transistor may be coupled to floating diffusion node 622, in this embodiment, dual floating-diffusion node signal DFD 1 may be de-asserted after the S&H circuit samples the image voltage from photodiode 611 at time 715. Additionally, dual floating-diffusion node signal DFD2 may be de-asserted after the S&H circuit samples the image voltage from photodiode 613 at time 735.

In another embodiment, said row select transistor may be omitted, and SF transistor 609 may be connected to bit line BL. In this embodiment, from time 710 to 750, during the readout of the photodiodes in four-shared pixel cell 600, row select power rail RSVDD is asserted, during the integration of photodiodes 611 and 612, row select power rail RSVDD is de-asserted.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize. For example, in one embodiment, RS transistor 610 may be omitted from the pixel cells. The omission of RS transistor 610 would not affect the operation of the pixel cells during ambient light detection mode. In one embodiment two or more photodiodes share the pixel circuitry of a pixel cell, such as reset transistor, source follower transistor or row select transistor.

Modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An imaging sensor pixel comprising:
a first photosensitive element to acquire a first image charge;
a second photosensitive element to acquire a second image charge;
a first transfer gate transistor to selectively transfer the first image charge from the first photosensitive element to a first floating diffusion (FD) node;
a second transfer gate transistor to selectively transfer the second image charge from the second photosensitive element to a second FD node;
a dual FD switch to selectively couple the first FD node and the second FD node; and
a source-follower transistor (SF) coupled to the dual FD switch to output the image charge from the first and second FD nodes.

2. The imaging sensor pixel of claim 1, wherein the second photosensitive element and the first photosensitive element comprise the same photosensitivity.

3. The imaging sensor pixel of claim 1, wherein the second photosensitive element comprises a photosensitivity greater than the first photosensitive element.

4. The imaging sensor pixel of claim 3, wherein the first photosensitive element is configured for low conversion gain.

5. The imaging sensor pixel of claim 3, wherein the second photosensitive element is configured for high conversion gain.

6. The imaging sensor pixel of claim 1, wherein the first and second photosensitive elements are disposed within a semiconductor die for accumulating an image charge in response to light incident upon a backside of the imaging sensor pixel.

7. The imaging sensor pixel of claim 1, wherein the first and second photosensitive elements are disposed within a semiconductor die for accumulating an image charge in response to light incident upon a front-side of the imaging sensor pixel.

8. The imaging pixel of claim 1, further comprising:
a third photosensitive element to acquire a third image charge;
a fourth photosensitive element to acquire a fourth image charge;
a third transfer gate transistor to selectively transfer the third image charge from the third photosensitive element to a third FD node;
a fourth transfer gate transistor to selectively transfer the fourth image charge from the fourth photosensitive element to a fourth FD node; and
a second dual FD switch to selectively couple the third and fourth FD nodes;
wherein the SF transistor is further coupled to the second dual FD switch to output the image charge from the third and fourth FD nodes.

9. A system comprising:
an array of imaging pixels wherein each imaging pixel includes:
a first photosensitive element to acquire a first image charge;
a second photosensitive element to acquire a second image charge;
a first transfer gate transistor to selectively transfer the first image charge from the first photosensitive element to a first floating diffusion (FD) node;
a second transfer gate transistor to selectively transfer the second image charge from the second photosensitive element to a second FD node;
an dual FD switch to selectively couple the first and second FD nodes; and
a source-follower transistor (SF) coupled to the dual FD switch to output the image charge from the first and second FD nodes;
a controlling unit coupled to the array of imaging pixels to control image data capture of the array of imaging pixels; and
readout circuitry coupled to the array of imaging pixels to readout the image data from each of the imaging pixels.

10. The system of claim 9, wherein, for each imaging pixel of the array of imaging pixels, the second photosensitive element and the first photosensitive element comprise the same photosensitivity.

11. The system of claim 9 wherein, for each imaging pixel of the array of imaging pixels, the second photosensitive element comprises a photosensitivity greater than the first photosensitive element.

12. The system of claim 11 wherein, for each imaging pixel of the array of imaging pixels, the first photosensitive element is configured for low conversion gain.

13. The system of claim 11 wherein, for each imaging pixel of the array of imaging pixels, the second photosensitive element is configured for high conversion gain.

14. The system of claim 9 wherein, for each imaging pixel of the array of imaging pixels, the first and second photosensitive elements are disposed within a semiconductor die for accumulating an image charge in response to light incident upon a backside of the imaging pixel.

15. The system of claim 9 wherein, for each imaging pixel of the array of imaging pixels, the first and second photosensitive elements are disposed within a semiconductor die for accumulating an image charge in response to light incident upon a front-side of the imaging pixel.

16. The system of claim 11, wherein the array of imaging pixels further includes:
a third photosensitive element to acquire a third image charge;
a fourth photosensitive element to acquire a fourth image charge;
a third transfer gate transistor to selectively transfer the third image charge from the third photosensitive element to a third FD node;
a fourth transfer gate transistor to selectively transfer the fourth image charge from the fourth photosensitive element to a fourth FD node; and
a second dual FD switch to selectively couple the third and fourth FD nodes,;
wherein the SF transistor is further coupled to the second dual FD switch to output the image charge from the third and fourth FD nodes.

17. A method comprising:
selectively transferring a first image charge from a first photosensitive element to a first floating diffusion (FD) node;
selectively transferring a second image charge from a second photosensitive element to a second FD node;
selectively coupling, via a dual FD switch, the first FD node and the second FD node; and
outputting the image charge from the first and second FD nodes via a source-follower transistor (SF) coupled to the dual FD switch.

18. The method of claim 17, wherein the second photosensitive element and the first photosensitive element comprise the same photosensitivity.

19. The method of claim 17, wherein the second photosensitive element comprises a photosensitivity greater than the first photosensitive element.

20. The method of claim 17, wherein the first photosensitive element is configured for low conversion gain and the second photosensitive element is configured for high conversion gain.
